(19) United States
(12) Patent Application Publication
(10) Pub. No.: US 2012/0243297 A1
(43) Pub. Date: Sep. 27, 2012

(54) RESISTANCE CHANGE TYPE MEMORY

(76) Inventors: Akira KATAYAMA, Yamato-shi (JP); Yoshihiro Ueda, Yokohama-shi (JP)

(21) Appl. No.: 13/428,312

(22) Filed: Mar. 23, 2012

(30) Foreign Application Priority Data
Mar. 24, 2011 (JP) 2011-066179

(51) Int. Cl. G11C 11/00

(52) U.S. Cl. 365/148

(57) ABSTRACT

According to one embodiment, a resistance change type memory includes first to third bit lines, a word line and a memory cell connected to the first to third bit lines and the word line. The memory cell includes a first transistor and a first memory element between the first and third bit lines, a second transistor and a second memory element between the second and third bit lines. Control terminals of the first and second transistors are connected to the word line. The resistance states of the first and second memory elements change to the first or second resistance state in accordance with a write pulse.

### CROSS-REFERENCE TO RELATED APPLICATIONS

This application is based upon and claims the benefit of priority from prior Japanese Patent Application No. 2011-066179, filed Mar. 24, 2011, the entire contents of which are incorporated herein by reference.

### FIELD

Embodiments described herein relate generally to a resistance change type memory.

### BACKGROUND

As next-generation semiconductor memories, resistance change type memories have been attracting attention, such as a magnetoresistive RAM (MRAM), a resistive RAM (ReRAM), and a phase change RAM (PCRAM). The resistance change type memories relatively easily allow element miniaturization and therefore enable the increase of storage density and the reduction of power consumption.

However, operation margins in the resistance change type memories may deteriorate in response to the increase of circuit integration and the reduction of a power supply voltage.

### BRIEF DESCRIPTION OF THE DRAWINGS

FIG. 1 is a diagram showing the overall configuration of a resistance change type memory according to an embodiment;

FIG. 2 is a diagram explaining the structure of a memory element;

FIG. 3 is a diagram explaining the internal configuration of a memory cell array; FIG. 4 is a diagram explaining a data retention state of a memory cell;

FIG. 5 is a diagram explaining the connection between the memory cell and a write circuit;

FIG. 6 is a diagram explaining the connection between the memory cell and a read circuit;

FIG. 7 is a chart explaining the operation of the resistance change type memory according to the embodiment;

FIG. 8 is a chart explaining the operation of the resistance change type memory according to the embodiment;

FIG. 9 is a diagram explaining a modification of the resistance change type memory according to the embodiment;

FIG. 10 is a diagram explaining the modification of the resistance change type memory according to the embodiment;

FIG. 11 is a chart explaining a modification of the resistance change type memory according to the embodiment;

FIG. 12 is a diagram explaining a modification of the resistance change type memory according to the embodiment; and

FIG. 13 is a diagram explaining the modification of the resistance change type memory according to the embodiment.

### DETAILED DESCRIPTION

Hereinafter, an embodiment will be described in detail with reference to the drawings. In the following explanation, elements having the same function and configuration are given the same reference signs and are repeatedly described when necessary.

In general, according to one embodiment, a resistance change type memory includes first to third bit lines extending in a first direction; a word line extending in a second direction, the second direction intersecting with the first direction; and a memory cell including a first cell connected between the first and third bit lines and a second cell connected between the second and third bit lines. The first cell includes a first transistor and a first memory element, the first transistor including a first control terminal connected to the word line and a first current path, the first memory element including a first terminal connected to one end of the first current path and a second terminal, the resistance state of the first memory element changing to a first resistance state or a second resistance state different from the first resistance state in accordance with a write pulse to be supplied. The second cell includes a second transistor and a second memory element, the second transistor including a second control terminal connected to the word line and a second current path, the second memory element including a third terminal connected to one end of the second current path and a fourth terminal, the resistance state of the second memory element changing to the first or second resistance state in accordance with a write pulse to be supplied.

### (1) Embodiments

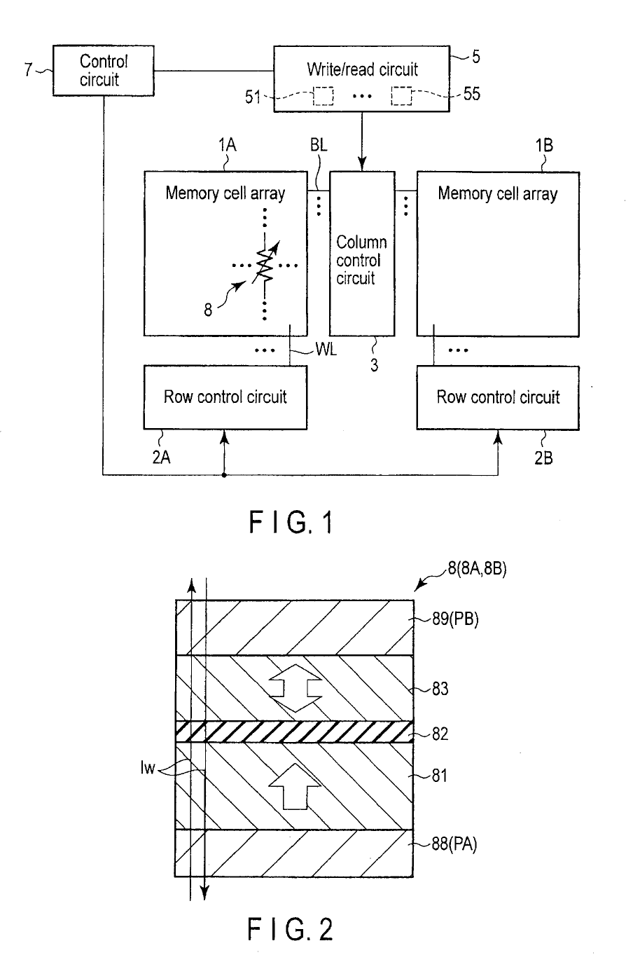

A resistance change type memory according to the embodiment is described with reference to FIG. 1 to FIG. 8.

(a) Circuit Configuration

The circuit configuration of the resistance change type memory according to the embodiment is described with reference to FIG. 1 to FIG. 6.

FIG. 1 is a block diagram showing a configuration example of the resistance change type memory according to the embodiment.

As shown in FIG. 1, the resistance change type memory according to the embodiment includes at least one memory cell array 1A or 1B. Although two memory cell arrays 1A and 1B are shown by way of example in FIG. 1, the resistance change type memory according to the embodiment has only to comprise one memory cell array 1A. However, the resistance change type memory according to the embodiment may comprise three or more memory cell arrays.

The memory cell arrays 1A and 1B comprise memory elements 8. Word lines WL and bit lines BL are provided in the memory cell arrays 1A and 1B. Each of the word lines WL extends in a row direction (second direction), and each of the bit lines BL extends in a column direction (first direction).

The resistance change type memory according to the embodiment includes row control circuits 2A and 2B, and a column control circuit 3.

The two row control circuits 2A and 2B are provided in the resistance change type memory according to the embodiment to respectively correspond to the two memory cell arrays 1A and 1B. The row control circuit 2A is adjacent to, for example, one end of the memory cell array 1A in the row direction. The row control circuit 2B is adjacent to one end of the memory cell array 1B in the row direction. The row control circuits 2A and 2B control the rows of the memory cell arrays 1A and 1B, respectively. The row control circuits 2A and 2B drive the word line WL connected to a memory cell. The row control circuits 2A and 2B comprise, for example, row decoders and word line drivers.

The column control circuit 3 is provided between the two memory cell arrays 1A and 1B, and is shared by the two memory cell arrays 1A and 1B. The column control circuit 3 is adjacent to the memory cell arrays 1A and 1B in the column direction. The column control circuit 3 controls the columns of the memory cell arrays 1A and 1B, and controls the potential of the bit line BL connected to a memory cell MC. The column control circuit 3 includes a column decoder, a column selecting switch (bit line selecting switch), and others.

The resistance change type memory according to the embodiment includes a write circuit for writing data into the memory cell, and a read circuit for reading data from the memory cell.

The write circuit and read circuit (hereinafter referred to as a write/read circuit) 5 are connected to the memory cell arrays 1A and 1B via the column control circuit 3. The write/read circuit 5 supplies, to the bit line BL via the column control circuit 3, a current (or voltage) used to write data and read data. The write/read circuit 5 includes a driver/sinker 51 including a current source (or voltage source), and a sense amplifier 55 for determining data in the memory cell in data reading.

A control circuit 7 controls the operation of the whole memory in response to a request from the external (a host or a memory controller). The control circuit 7 controls the row control circuits 2A and 2B, the column control circuit 3, and the write/read circuit 5 to write data into or read data from a selected memory cell.

The resistance change type memory uses, as a memory element 8, an element 8 that changes in resistance state.

The resistance value (resistance state) of the memory element 8 used in the resistance change type memory changes when energy (a current, a voltage, or heat) having a given threshold is supplied to the memory element 8. The changed resistance state is maintained substantially in a nonvolatile manner until the predetermined energy is applied. Using such element characteristics, data associated with the resistance state of the element is stored in the resistance change type memory.

The resistance state of the memory element 8 is changed by the polarity (application direction) of a current pulse or a voltage pulse, by the intensity (current value, voltage value and pulse width) of the current pulse or the voltage pulse, or by heat generated by these pulses.

The resistance change type memory according to the embodiment is, for example, a magnetoresistive RAM (MRAM). The memory element 8 is a magnetoresistive effect element. For example, a magnetic tunnel junction (MTJ) element is used as the memory element 8.

FIG. 2 is a sectional view showing the configuration of the MTJ element 8. The MTJ element 8 has a stack structure including a lower electrode 88, a reference layer (also referred to as a magnetization invariable layer, a pin layer, or a pinned layer) 81, a nonmagnetic layer (also referred to as a tunnel barrier layer) 82, a recording layer (also referred to as a magnetization variable layer, a storage layer, or a free layer) 83, and an upper electrode 89. The layers 81, 82, and 83 may be stacked in an order reverse to that shown in FIG. 2.

The reference layer 81 and the recording layer 83 are made of a ferromagnetic material having Ni, Cr, or Co. The reference layer 81 and the recording layer 83 have magnetic anisotropy, for example, in a direction perpendicular to a film plane, and the easy magnetization directions thereof are perpendicular to the film plane. The magnetization directions of the reference layer 81 and the recording layer 83 may be parallel to the film plane.

The reference layer 81 is fixed (invariable) in the direction of its magnetization (spin). The recording layer 83 is inverted (variable) in the direction of its magnetization (spin).

The reference layer 81 is formed to have perpendicular magnetic anisotropy energy sufficiently higher than that of the recording layer 83. The magnetic anisotropies of the magnetic layers 81 and 83 can be set by adjusting the material constitution and thickness thereof. In the MTJ element 8, the magnetization inversion threshold of the recording layer 83 is low, and the magnetization inversion threshold of the reference layer 81 is higher than the magnetization inversion threshold of the recording layer 83. Thus, the MTJ element 8 having the reference layer 81 fixed in magnetization direction and the recording layer 83 variable in magnetization direction can be formed.

In the present embodiment, a spin-torque-transfer writing method is used as a memory writing method to pass a write current (current pulse) Iw through the MTJ element 8 and thereby control the magnetization state of the MTJ element 8. The intensity of the write current Iw is set so that the write current Iw has a value which is equal to or more than the magnetization inversion threshold of the recording layer 83 and which is less than the magnetization inversion threshold of the reference layer 81. The MTJ element 8 can take at least two resistance states depending on the direction in which the write current Iw runs.

The MTJ element 8 can take one of two states including a high-resistance state and a low-resistance state, depending on whether the magnetizations of the reference layer 81 and the recording layer 83 are parallel or antiparallel to each other.

If the write current Iw running from the recording layer 83 to the reference layer 81 is passed through the MTJ element 8 in which the magnetizations are arranged antiparallel to each other, electrons having a spin in the same direction as the magnetization arrangement of the reference layer 81 predominate as electrons supplied to the recording layer 83 via the nonmagnetic layer 82.

The magnetization direction of the recording layer 83 is changed (inverted) to the same direction as the magnetization direction of the reference layer 81 by the spin torque of the electrons which have passed (tunneled) through the nonmagnetic layer 82. As a result, the magnetizations of the reference layer 81 and the recording layer 83 change from the antiparallel state to the parallel state.

When the magnetizations of the reference layer 81 and the recording layer 83 are arranged parallel to each other, the resistance value of the MTJ element 8 is minimized. When the MTJ element 8 has a parallel magnetization arrangement, the MTJ element 8 is in the low-resistance state.

If the write current Iw running from the reference layer 81 to the recording layer 83 is passed through the MTJ element 8 in which the magnetizations are arranged in parallel, electrons having a spin in the same direction as the magnetization arrangement of the reference layer 81 move to the reference layer 81 via the nonmagnetic layer 82. In the meantime, electrons having a spin in a direction opposite to the magnetization arrangement of the reference layer 81 are reflected to the recording layer 83 by the nonmagnetic layer 82 or the reference layer 81. The magnetization direction of the recording layer 83 is changed to a direction opposite to the magnetization direction of the reference layer 81 by the spin torque of the reflected electrons. As a result, the magnetizations of the recording layer 83 and the reference layer 81 change from the parallel state to the antiparallel state.

When the magnetizations of the reference layer 81 and the recording layer 83 are arranged antiparallel to each other, the resistance value of the MTJ element 8 is maximized. When the MTJ element 8 has the antiparallel magnetization arrangement, the MTJ element 8 is in the high-resistance state.

As described above, the resistance state of the MTJ element 8 changes in accordance with the direction (polarity) of the current pulse which runs, through the MTJ element 8 and which is equal to or more than the magnetization inversion threshold. Hereinafter, in a memory element such as the MTJ element which changes in resistance state in accordance with the direction (polarity) of the pulse supplied to the element, one terminal PB may be referred to as a first-polarity terminal (here, the electrode 89 on the side of the recording layer 83), and the other terminal PA may be referred to as a second-polarity terminal (here, the electrode 88 on the side of the reference layer 81). For example, the variable resistance state of the memory element is different (opposite) depending on whether the write current runs from the first-polarity terminal PB to the second-polarity terminal PA or the write current runs from the second-polarity terminal PA to the first-polarity terminal PB.

A current (read pulse) is supplied to the MTJ element 8 to judge the resistance state of the MTJ element 8. The current for judging the resistance state has a value less than the magnetization inversion threshold of the recording layer 83.

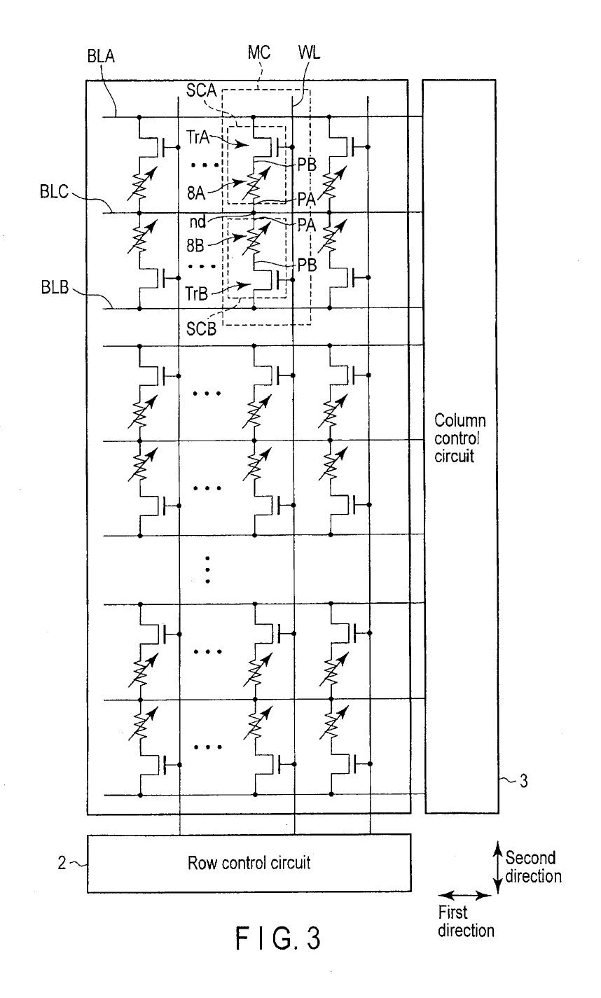

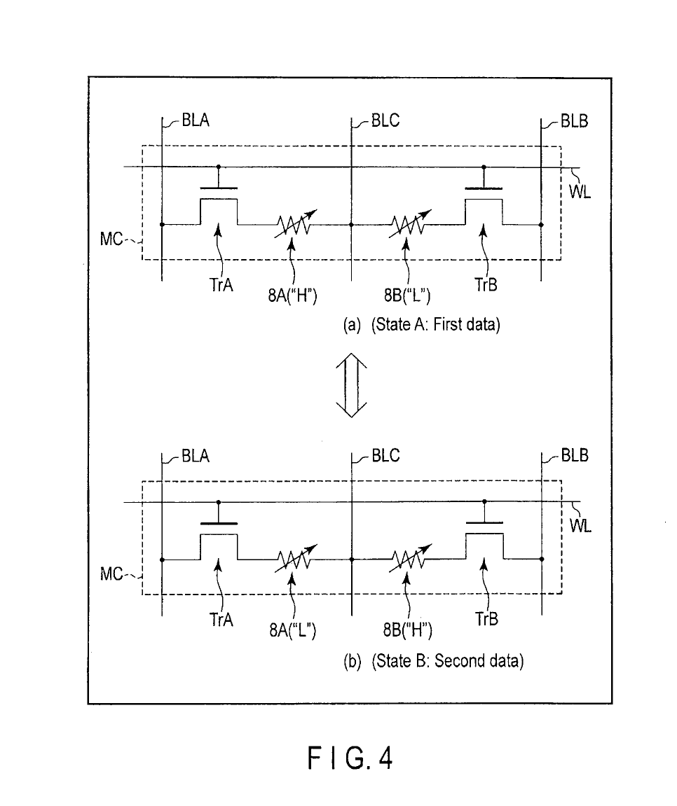

FIG. 3 is an equivalent circuit diagram showing an example of the internal configuration of the memory cell array 1A in the resistance change type memory according to the embodiment. The MTJ element is shown below as an example of the memory element.

As shown in FIG. 3, memory cells MC, word lines WL, and bit lines BLA, BLB, and BLC are provided in the memory cell array 1A.

One word line WL and three bit lines BLA, BLB, and BLC are connected to each memory cell MC.

The memory cells MC arrayed in the row direction are connected to the common word line WL. The memory cells MC arrayed in the column direction are connected to the shared bit lines BLA, BLB, and BLC.

The memory cell MC in the resistance change type memory according to the embodiment is formed of two field effect transistors (T) TrA and TrB and two MTJ elements (R) 8A and 8B. The memory cell MC has a 2T+2R structure. In the present embodiment, the internal configuration of the memory cell MC having the 2T+2R structure, and the connection between the memory cell MC and the interconnects WL, BLA, BLB, and BLC are as follows.

The field effect transistors TrA and TrB are used as selection switches for the memory cell MC. The field effect transistors TrA and TrB of the memory cell MC are referred to as select transistors TrA and TrB.

The gates of the two select transistors TrA and TrB in the memory cell MC are connected to the common word line WL.

One end (source/drain) of the current path (first current path) of the first select transistor TrA is connected to the first bit line BLA. The other end (source/drain) of the current path of the first select transistor TrA is connected to one end (first terminal) of the first MTJ element 8A. The other end (second terminal) of the MTJ element 8A is connected to one end (third terminal) of the second MTJ element 8B. The other end (fourth terminal) of the MTJ element 8B is connected to one end (source/drain) of the current path of the second select transistor TrB. The other end (source/drain) of the current path of the select transistor TrB is connected to the second bit line BLB.

The terminals of the two MTJ elements 8A and 8B connected to each other form a connection node nd. The bit line BLC is connected to the connection node nd formed in the memory cell MC. For ease of understanding, the bit line BLC connected to the connection node nd is hereinafter referred to as a shared bit line BLC.

In the cells SCA and SCB, the current paths of the memory elements 8A and 83 are connected in series to the current paths of the select transistors TrA and TrB.

In the present embodiment, for example, the terminals (electrodes) PA of the MTJ elements 8A and 8B on the side of the reference layers 81 are connected to the connection node nd. However, the terminals of the two MTJ elements 8A and 8B having the same polarity have only to be connected to the connection node nd. Thus, the terminals PB of the two MTJ elements 8A and 8B on the side of the recording layers 83 may be connected to the connection node nd.

The connection of the MTJ elements to the select transistors between the bit lines BLA, BLB, and BLC is not limited to the example shown in FIG. 3. For example, between the bit line BLA and the shared bit line BLC, one end of the MTJ element 8A may be connected to the bit line BLA, the other end of the MTJ element 8B may be connected to one end of the current path of the select transistor TrA, and the other end of the current path of the select transistor TrC may be connected to the shared bit line BLC. Between the shared bit line BLC and the bit line BLB, one end of the current path of the select transistor TrB is connected to the shared bit line BLC, the other end of the current path of the select transistor TrB is connected to one end of the MTJ element 8B, and the other end of the MTJ element 8B is connected to a bit line BL2. In this case, the two select transistors TrA and TrB form the connection node nd to which the shared bit line BLC is connected.

Hereinafter, in one memory cell MC, a circuit comprising one MTJ element (memory element) and one select transistor is referred to as a cell SCA or SCB. One memory cell MC is formed of the two cells SCA and SCB.

The data retention state of the resistance change type memory according to the embodiment is described with reference to FIG. 4.

FIG. 4 shows the resistance states of the memory elements (MTJ elements) 8A and 8B in the memory cell MC when data is retained in the resistance change type memory according to the embodiment.

For example, when data is retained in the memory cell MC, the two MTJ elements 8A and 8B in the memory cell MC have different resistance states.

For example, as shown in (a) of FIG. 4, when the resistance state (resistance level) of one MTJ element 8A is the high-resistance state (“H” level), the resistance state of the other MTJ element 8B is the low-resistance state (“L” level). In contrast, as shown in (b) of FIG. 4, when the resistance state of one MTJ element 8A is the low-resistance state, the resistance state of the other MTJ element 8B is the high-resistance state.

In this way, the memory cell MC maintains the state (state A) of (a) in FIG. 4 or the state (state B) of (b) in FIG. 4 substantially in a nonvolatile manner depending on data to be stored (written data).

Data “1” (first data) is assigned to, for example, the state in which one MTJ element 8A in the memory cell MC is at the “H” level and the other MTJ element 8B is at the “L” level. On the other hand, data “0” (second data) is assigned to, for example, the state in which one MTJ element 8A in the memory cell MC is at the “L” level and the other MTJ element 8B is at the “H” level. Thus, the memory cell MC having two memory elements 8A and 8B can retain one-bit data.

However, in the present embodiment, during a later-described write operation, the resistance state of one memory element may be changed after the two memory elements 8A and 8B in the memory cell MC are set in the same resistance state. Therefore, in a transitional state during the writing of data into the memory cell MC, the two MTJ elements 8A and 8B in the memory cell MC show the same resistance state. Alternatively, each of the two MTJ elements in the memory cell MC may retain one-bit data. In this case, one memory cell MC is configured to store two-bit (multilevel) data. For example, data “1” is assigned to the “H” level of the MTJ element, and data “0” is assigned to the “L” level of the MTJ element.

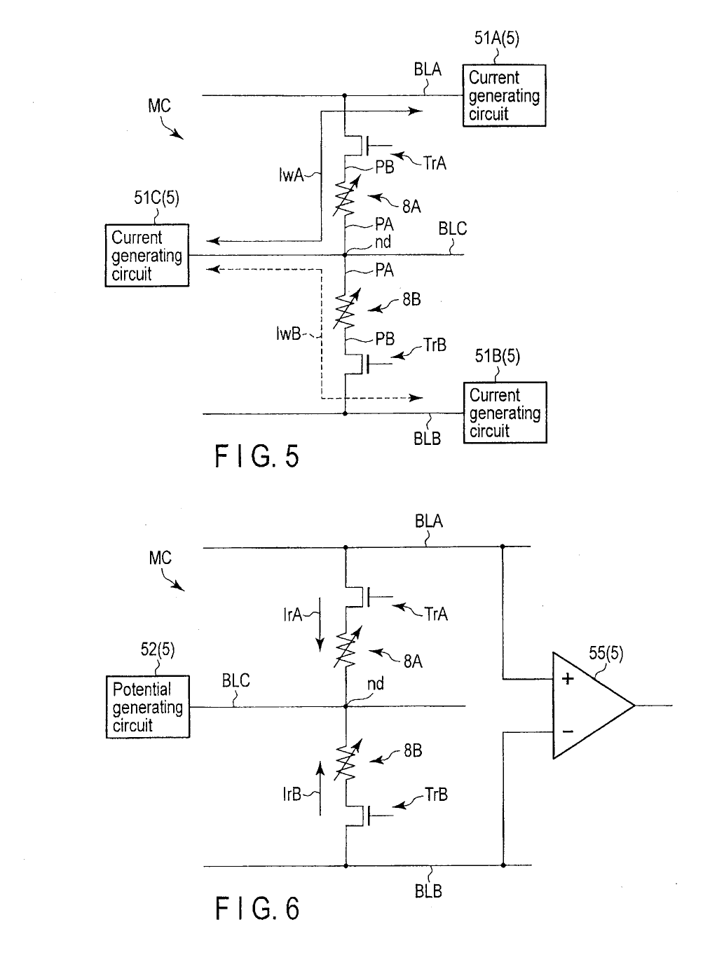

FIG. 5 and FIG. 6 show the connection between the memory cell MC and the write/read circuit 5 during the operation of the memory cell MC. In FIG. 5 and FIG. 6, the configuration of the column control circuit 3 connected between the memory cell MC and the write/read circuit 5 is not shown for the simplicity of the drawings. The word line WL is not shown in FIG. 5 and FIG. 6 either.

FIG. 5 is an equivalent circuit diagram showing an example of the connection between the memory cell MC and the write/read circuit 5 during data writing.

During data writing, current generating circuits 51A, 51B, and 51C in the write/read circuit 5 are connected to the memory cell MC.

The current generating circuits 51A, 51B, and 51C comprise, for example, current sources or voltage sources for generating write currents IwA and IwB. The current generating circuits 51A, 51B, and 51C generate the write currents IwA and IwB, and supply the write currents IwA and IwB to the memory cell MC targeted for data writing. The write currents IwA and IwB may be generated by the voltage sources.

During the writing of data into the memory cell MC, the first current generating circuit 51A is connected to the bit line BLA, the second current generating circuit 51B is connected to the second bit line BLB, and the third current generating circuit 51C is connected to the shared bit line BLC.

As has been described with reference to FIG. 2, in order to change the resistance states of the MTJ elements 8A and 8B, the write currents IwA and IwB run from one end of the MTJ elements to the other or from the other end of the MTJ elements to one end depending on the resistance state to be changed.

The write currents IwA and IwB run across the bit line BLA and the shared bit line BLC and across the bit line BLB and the shared bit line BLC.

In order to change the resistance state of the MTJ elements 8A, the write current IwA is supplied across the bit line BLA and the shared bit line BLC.

When the write current IwA runs from the bit line BLA to the shared bit line BLC, the current generating circuit 51A serves as a supply side (high-potential side or driver side), and the current generating circuit 51C serves as an absorption side (low-potential side or sink side). In contrast, when the write current IwA runs from the shared bit line BLC to the bit line BLA, the current generating circuit 51C serves as a supply side, and the current generating circuit 51A serves as an absorption side.

In order to change the resistance state of the MTJ elements 8B, the write current IwB is supplied across the bit line BLB and the shared bit line BLC.

When the write current IwB runs from the bit line BLB to the shared bit line BLC, the current generating circuit 51B serves as a supply side, and the current generating circuit 51C serves as an absorption side. In contrast, when the write current IwB runs from the shared bit line BLC to the bit line BLB, the current generating circuit 51C serves as a supply side, and the current generating circuit 51B serves as an absorption side.

The control circuit 7 controls whether to set the current generating circuits 51A, 51B, and 51C to the high-potential side or the low-potential side in accordance with data to be written into the memory cell.

The potentials of the bit lines BLA, BLB, and BLC are controlled to prevent any current from running to the bit line BLB from the bit line BLA.

For example, in order to write into the MRAM according to the present embodiment, the two MTJ elements in the memory cell MC are changed to the same resistance state, and then the resistance state of one of the MTJ elements is changed, in a write cycle (one period in which the word line is activated) for the memory cell MC targeted for data writing. After the data writing, the two MTJ elements 8A and 8B in the memory cell have different resistance states, as shown in FIG. 4. FIG. 6 is an equivalent circuit diagram showing an example of the connection between the memory cell MC and the write/read circuit 5 during data reading.

As shown in FIG. 6, the sense amplifier 55 in the write/read circuit 5 is connected to the memory cell MC during data reading.

One input terminal of the sense amplifier 55 is connected to the bit line BLA, and the other input terminal of the sense amplifier 55 is connected to the bit line BLB. The bit line BLA and the bit line BLB are set to, for example, the same potential level. The shared bit line BLC is connected to, for example, a potential generating circuit 52. The potential generating circuit 52 generates a predetermined potential, and applies the generated potential to the shared bit line BLC.

During data reading, for example, the bit lines BLA and BLB are set to the high-potential side, and the shared bit line BLC is set to the low-potential side. In this case, the shared bit line BLC is connected to a ground potential (grounded). As long as the shared bit line BLC is different in potential level from the bit lines BLA and BLB, the shared bit line BLC may be set to the high-potential side, and the bit lines BLA and BLB may be set to the low-potential side.

During data reading, read currents (read pulses) IrA and IrB run through the MTJ elements 8A and 8B as a result of a potential difference set between the bit lines BLA, BLB, and BLC. The read current IrA may be generated by the current source (not shown) connected to the bit line BLA, and the read current IrB may be generated by the current source (not shown) connected to the bit line BLB. The values of the read currents IrA and IrB are set to values lower than the magnetization inversion threshold.

The value of the read current IrA (or the potential of the bit line BLA) varies in accordance with the resistance state (resistance value) of the MTJ element 8A. Similarly, the value of the read current IrB (or the potential of the bit line BLB) varies in accordance with the resistance state (resistance value) of the MTJ element 8B.

The sense amplifier 55 detects and amplifies the values (potentials) of the currents running through the bit lines BLA and BLB connected to the input terminals of this sense amplifier. The sense amplifier 55 calculates a difference value between the current values (or potentials) of the two bit lines BLA and BLB, and then outputs the difference value. In accordance with this difference value, the data stored in the memory cell MC is determined by, for example, the control circuit 7 or an external device.

For example, the MRAM according to the present embodiment is read by differential reading that uses the two MTJ elements 8A and 8B included in the memory cell MC targeted for data reading.

In the MRAM according to the present embodiment, the memory cell MC is formed of the two MTJ elements 8A and 8B and the two select transistors TrA and TrB. In the memory cell MC, one MTJ element 8A or 8B and one select transistor TrA or TrB form one cell SCA or SCB. One shared bit line BLC is connected to the two cells SCA and SCB. The MTJ element 8A is connected between the bit line BLA and the shared bit line BLC via the select transistor TrA. The MTJ element 8B is connected between the bit line BLB and the shared bit line BLC via the select transistor TrB.

In the MRAM according to the present embodiment, the two MTJ elements 8A and 8B and the two select transistors TrA and TrB are provided in the same memory cell array 1A. Thus, the characteristic variations of the MTJ elements 8A and 8B forming the memory cell MC and the characteristic variations of the select transistors TrA and TrB forming the memory cell MC can be reduced in the MRAM according to the present embodiment as compared with the case where the two MTJ elements 8A and 8B and the two select transistors TrA and TrB forming the memory cell MC are provided in different memory cell arrays. Consequently, the MRAM according to the present embodiment enables the stabilization of the write operation and the read operation of the memory cell and the improvement of the memory operation.

In the MRAM according to the present embodiment, one bit line (shared bit line) BLC is shared by the two MTJ elements 8A and 8B. Therefore, during the write operation and the read operation, the variation of the currents supplied to the two MTJ elements 8A and 8B can be reduced. Consequently, the MRAM according to the present embodiment enables the improvement of a writing margin and a reading margin in its operation.

The use of the two MTJ elements 8A and 8B having different resistance states in the data retention state of the memory cell MC in the MRAM according to the present embodiment enables the differential reading of one memory cell. One memory cell can be differentially read such that the reading margin of the memory can be larger than when data is read from one memory cell by single-end reading. Moreover, the MTJ elements 8A and 83 that are driven by the differential reading are connected to the shared bit line BLC as in the present embodiment such that the variations of the read currents IrA and IrB detected by the sense amplifier 55 can be inhibited.

In a memory element used in a resistance change type memory such as the MTJ element used in the MRAM, the intensity and application period of the current pulse (voltage pulse) for changing the resistance state of the memory element from the “L” state to the “H” state may be different from the intensity and application period of the current pulse for changing the resistance state from the “H” state to the “L” state. In the present embodiment, the memory cell MC is formed so that the operation for changing the resistance state to the “L” state and the operation for changing the resistance state to the “H” state are performed in one write cycle. This allows the reduction of writing time in the whole memory cell array.

Consequently, the resistance change type memory according to the present embodiment enables improved memory operation characteristics.

(b) Operation

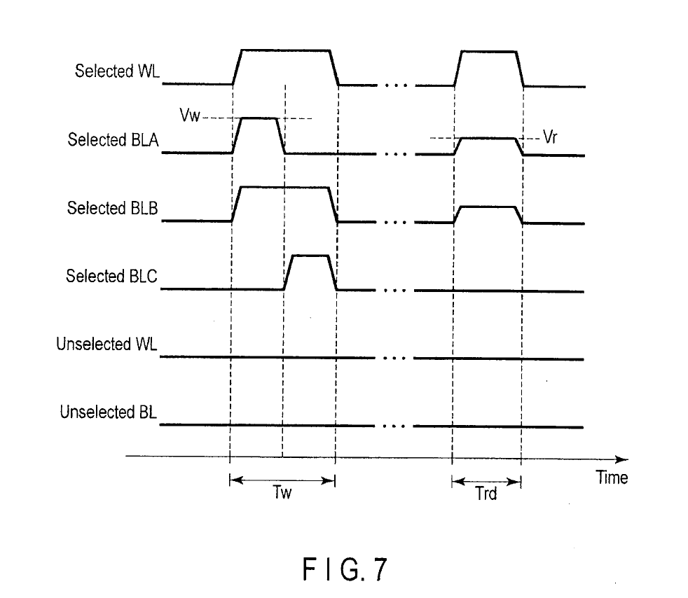

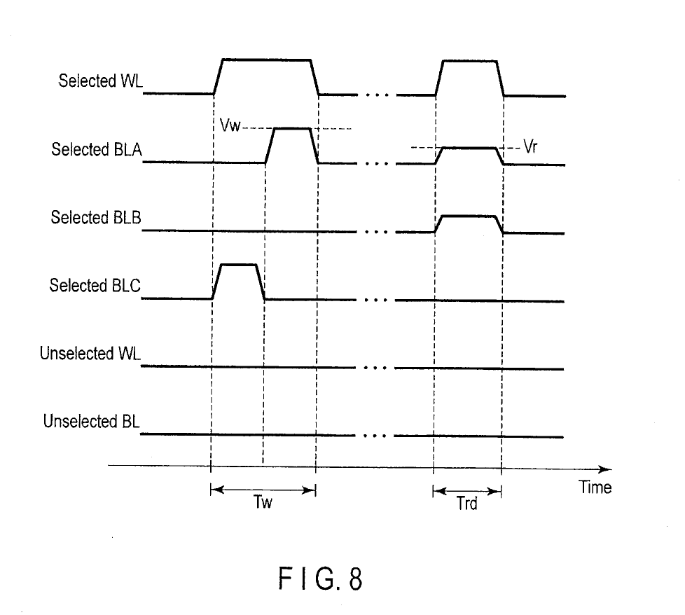

The operation of the resistance change type memory (e.g., MRAM) according to the present embodiment is described with reference to FIG. 7 and FIG. 8. FIG. 1 to FIG. 6 are also appropriately used to describe the operation of the MRAM according to the present embodiment.

An example of the operation of the MRAM according to the present embodiment is described with reference to FIG. 7. FIG. 7 shows a timing chart of examples of the write operation and read operation in the MRAM according to the present embodiment.

In the MRAM according to the present embodiment, the two MTJ elements 8A and 8B in one memory cell MC are set to the same resistance state in one write cycle, and then the resistance state of one of the two MTJ elements 8A and 8B is changed in the same write cycle. As a result, the two MTJ elements 8A and 8B in one memory cell MC are set in different resistance states, and data is written into the memory cell.

FIG. 7 shows, by way of example, the write operation in which in a write cycle, a current running from one bit line BLA and the other bit line BLB to the shared bit line BLC is passed and then a write current running from the shared bit line BLC to one bit line alone is passed. Here, data writing is shown by way of example in which the two MTJ elements 8A and 8B in the memory cell MC are set to the “L” state and then one memory element is set to the “H” state.

During the write operation, a write command, and an address of the memory cell MC targeted for writing are externally input to an MRAM chip.

In accordance with the input command and address, the control circuit 7 shown in FIG. 1 controls the operations of the row control circuits 2A and 2B, the column control circuit 3, and the write/read circuit 5.

Under the control of the control circuit 7, the row control circuits 2A and 2B select a word line (referred to as a selected word line) indicated by the input address, and activate the selected word line.

Under the control of the control circuit 7, the column control circuit 3 selects bit lines (referred to as selected bit lines) indicated by the input address, and activates the selected bit lines.

As shown in FIG. 5, the current generating circuits 51A, 51B, and 51C in the write/read circuit 5 are electrically connected to the selected bit lines via the column control circuit under the control of the control circuit 7.

As a result, a memory cell (referred to as a selected cell) connected to the selected word line and the selected bit lines is activated.

In the meantime, the control circuit 7 sets unselected word lines WL and unselected bit lines BLA, BLB, and BLC to, for example, the “L” level. The unselected bit lines BLA, BLB, and BLC are set to the same potential such that no current is supplied to unselected cells. As long as the potentials of the unselected bit lines BLA, BLB, and BLC are set to the same level to prevent current passage, a predetermined potential (e.g., a potential that does not allow the generation of a write current) may be applied to the unselected bit lines BLA, BLB, and BLC. The unselected bit lines are charged by this potential, and the operation of the memory can be faster when the selected bit lines are operated in succession.

Under the above-described control of the control circuit 7, the potential of the selected word line is set to the “H” level (transistor threshold voltage) from the “L” level, and the potentials of the word lines (unselected word lines) other than the selected word line are kept at the “L” level, as shown in FIG. 7. As a result, two select transistors in the memory cell connected to the selected word line are turned on.

When the three bit lines BLA, BLB, and BLC connected to the selected cell are activated, the selected bit lines BLA, BLB, and BLC are connected to the current generating circuits 51A, 51B, and 51C. In the example shown in FIG. 7, the current generating circuits (drivers) 51A and 51B connected to the bit lines BLA and BLB are set to a current supply side (also referred to as a high-potential side or “H” level) by, for example, the control circuit 7, and the potentials of the selected bit lines BLA and BLB shift from the “L” level to the “H” level (an inversion threshold voltage Vw of the MTJ element). The current generating circuit (sinker) 51C connected to the shared bit line BLC is set to a current absorption side (low-potential side) by the control circuit 7, and the potential of the selected bit line BLC is kept at the “L” level. Write currents IwA and IwB equal to or more than the magnetization inversion threshold are generated by the potential difference Vw between the bit lines BLA, BLC, and BLB.

In the selected cell MC, the write current IwA is supplied to the MTJ element 8A as a memory element via the select transistor TrA in an on-state. The write current IwA runs toward the shared bit line BLC at the “L” level from the bit line BLA at the “H” level.

In the selected cell MC, the write current IwB is supplied to the MTJ element 8B via the select transistor TrB in an on-state. The write current IwB runs toward the shared bit line BLC at the “L” level from the bit line BLB at the “H” level.

As described above, since the terminals PA of the reference layers (or recording layers) of the two MTJ elements 8A and BB are connected to the connection node nd, the write currents IwA and IwB in the same direction (of the same polarity) run through the two MTJ elements 8A and 8B in the selected cell MC. Therefore, the MTJ elements 8A and 8B are brought into the same resistance state. For example, when the terminals PA on the reference layer side of the MTJ elements BA and BB are connected to the connection node nd, the write currents IwA and IwB run from the recording layers to the reference layers, and spin-polarized electrons are supplied to the recording layers from the reference layers. The resistance states of the two MTJ elements BA and 8B in the selected cell MC become the “L” state (low-resistance state or set state). When the recording layers of the MTJ elements 8A and 8B are connected to the connection node nd, the resistance states of the two MTJ elements 8A and 8B become the “H” state (high-resistance state or reset state).

Thus, in the first half of a period (referred to as a selected word line activation period) in which the selected word line on a write cycle Tw is set at the “H” level, the two MTJ elements BA and 8B in the selected cell MC are set to the same resistance state.

The passage of the write currents from the bit lines BLA and BLB to the shared bit line BLC is followed by the passage of write currents from the shared bit line BLC to the bit lines BLA and BLB in the second half of the selected word line activation period. However, in this case, the potentials of the bit lines BLA, BLB, and BLC are controlled so that the write current is supplied to one of the two MTJ elements 8A and 8B in the selected cell and so that the write current is not supplied to the other MTJ element.

For example, in the example shown in FIG. 7, the write current from the side of the shared bit line BLC is supplied to the MTJ element 8A connected between the bit line BLA and the shared bit line BLC, and the write current from the side of the shared bit line BLC is not supplied to the MTJ element 8B connected between the bit line BLB and the shared bit line BLC.

More specifically, as shown in FIG. 7, in the period (activated period) of the selected word line at the “H” level, the current generating circuit (driver) 51C connected to the selected shared bit line BLC is changed from the current absorption side to the current supply side by the control circuit 7. Therefore, the potential of the shared bit line BLC shifts from the “L” level to the “H” level.

Substantially simultaneously with the control of the potential of the selected shared bit line BLC, the current generating circuit (sinker) 51A connected to the selected bit line BLA is changed from the current supply side to the current absorption side by the control circuit 7, and the potential of the bit line BLA shifts from the “H” level to the “L” level.

On the other hand, the potential of the selected bit line BLB is kept at the “H” level, and set to the same potential as the potential (here, the “H” level) of the shared bit line BLC.

As a result, the write current IwA directed from the shared bit line BLC to the bit line BLA runs through the MTJ element 8A connected to the bit line BLA. The resistance state of the MTJ element 8A is changed by the write current IwA. For example, electrons (electrons having a spin opposite to the spin of the reference layer) reflected by the reference layer of the MTJ element 8A are supplied to the recording layer of the MTJ element 8A, and the resistance state of the MTJ element 8A changes from the “L” state to the “H” state.

On the other hand, the potential difference between the bit line BLB and the shared bit line BLC is substantially 0 V. Therefore, no current that changes the resistance state of the MTJ element 8B runs through the MTJ element 8B connected to the bit line BLB. Thus, the MTJ element 8B is not changed in resistance state, and is kept in, for example, the “L” state.

After the MTJ elements in the selected cell are set to the same resistance state in the write cycle Tw, the potential of the bit line BLA may be set to be equipotential to the shared bit line BLC and a potential difference that generates a write current between the bit line BLB and the shared bit line BLC may be set so that the resistance state of the MTJ element 8A on the side of the bit line BLA is not changed and the resistance state of the MTJ element 8B on the side of the bit line BLB is changed in accordance with the data to be written into the memory cell.

After the two MTJ elements 8A and 8B in the selected cell are changed from the same resistance state to different resistance states in the write cycle (activation period), the potential of the selected word line WL is set to the “L” level from the “H” level under the control of the control circuit 7 and the row control circuits 2A and 2B, and the selected word line WL is inactivated. Accordingly, the select transistors TrA and TrB in the selected cell are turned off.

For example, after the selected word line WL is inactivated, the selected bit lines BLA, BLB, and BLC are inactivated under the control of the control circuit 7 and the column control circuit 3. Accordingly, the selected bit lines BLA, BLB, and BLC are electrically separated from the current generating circuits 51A, 51B, and 51C of the write/read circuit 5. The selected word line may be inactivated after the selected bit lines are inactivated.

If no write current runs, the unselected bit lines BLA, BLB, and BLC may be set to the same potential (e.g., a potential less than the “H” level) by the control circuit 7, and the unselected bit lines may be charged.

The write operation for the selected cell is completed as described above.

In a state after the data has been written (data retention state), the two MTJ elements 8A and 8B in the memory cell are in different resistance states. Here, one MTJ element 8A has a resistance state corresponding to the “H” state, and the other MTJ element 8B has a resistance state corresponding to the “L” state. Depending on the data to be written into the memory cell, the MTJ element 8A may have a resistance state corresponding to the “L” state, and the MTJ element 8B may have a resistance state corresponding to the “H” state.

Thus, in the write operation for the memory cell in the MRAM according to the present embodiment, the two MTJ elements 8A and 8B in the selected cell are set to the same resistance state, and then the resistance state of one of the two MTJ elements 8A and 8B in the selected cell is only changed in accordance with the data to be written.

Now, the read operation in the MRAM according to the present embodiment is described with reference to FIG. 7. It should be noted that the same control as that in the above-described write operation is described when necessary.

For example, the MRAM according to the present embodiment is read in response to an external request.

When the MRAM is read, a read command and an address of the memory cell targeted for reading are externally input to the MRAM chip.

In accordance with the input command and address, the control circuit 7 controls the operations of the row control circuits 2A and 2B, the column control circuit 3, and the write/read circuit 5.

Under the control of the control circuit 7, the row control circuits 2A and 2B activate a selected word line. Under the control of the control circuit 7, the column control circuit 3 activates selected bit lines.

As shown in FIG. 6, the sense amplifier 55 in the write/read circuit 5 is electrically connected to the selected bit lines via the column control circuit under the control of the control circuit 7.

As a result, a selected cell connected to the selected word line and the selected bit lines is activated.

Under the control of the control circuit 7, the bit line BLA to which the MTJ element 8A is connected is connected to one input terminal of the sense amplifier 55, and the bit line BLB to which the MTJ element 8B is connected is connected to the other input terminal of the sense amplifier 55, in the memory cell MC. The shared bit line BLC is connected to a predetermined potential (ground or power supply potential) in the potential generating circuit 52.

In a read cycle Trd during the read operation, the potentials of the unselected word lines WL and the unselected bit lines BLA, BLB, and BLC are set to the “L” level. However, as long as the unselected bit lines have the same potential, a potential may be applied to the unselected bit lines BLA, BLB, and BLC for faster operation.

A potential (or current) Vr is applied to the bit lines BLA and BLB under the control of the control circuit 7. The read currents IrA and IrB run through the MTJ elements 8A and BB as a result of a potential difference between the bit lines BLA and BLB and the shared bit line BLC.

In the memory cell MC, as the resistance state of the MTJ element 8A is different from the resistance state of the MTJ element 8B, the values of the read currents IrA and IrB running through the MTJ elements 8A and 8B are different. The sense amplifier 55 detects and amplifies the two read currents IrA and IrB or the potential variations of the bit lines BLA and BLC attributed to the currents IrA and IrB, and calculates a difference value between the current values. The difference value is output from the sense amplifier 55.

The potential Vr of the bit lines BLA and BLB is set to be sufficiently lower than the potential Vw applied to the bit lines BLA, BLB, and BLC during the write operation to the extent that the currents IrA and IrB running through the bit lines BLA and BLB or the potential variations of the bit lines BLA and BLB can be detected so that the resistance states of the memory elements BA and 8B are not changed due to the currents IrA and IrB generated by the potential Vr of the bit lines BLA and BLB.

After the read currents IrA and IrB are detected, the potential of the selected word line WL is shifted from the “H” level to the “L” level under the control of the control circuit 7 and the row control circuit 2A, and the selected word line is inactivated. Accordingly, the select transistors TrA and TrB in the selected cell are turned off.

Moreover, the selected bit lines BLA, BLB, and BLC are inactivated under the control of the control circuit 7 and the column control circuit 3, and the selected bit lines BLA, BLB, and BLC are electrically separated from the sense amplifier 55 and the potential generating circuit 52.

The data stored in the memory cell MC is determined in accordance with the difference value output from the sense amplifier 55. For example, the positive and negative (polarity) of the calculated difference value are associated with the data (e.g., “0” or “1”). That is, the difference value calculated in accordance with the resistance states of the two MTJ elements 8A and 8B is converted to the data stored in the memory cell and then output.

Thus, in the read operation for the memory cell in the MRAM according to the present embodiment, the data stored in the memory cell MC is determined by the differential reading that uses the two MTJ elements in the memory cell.

The operation different from the operation shown in FIG. 7 is described with reference to FIG. 8. FIG. 8 shows a timing chart of examples of the write operation and read operation in the MRAM according to the present embodiment. It should be noted that the same operation as that shown in FIG. 7 and its control are described when necessary.

As shown in FIG. 8, a selected word line WL and selected bit lines BLA, BLB, and BLC are activated, and a selected memory cell MC is activated.

For example, in the first half of the activation period of the selected word line in the write cycle Tw, the potential of the selected bit line BLA is set to the “L” level, the potential of the selected bit line BLB is set to the “L” level, and the potential of the shared bit line BLC is set to the “H” level. As a result, the write current IwA running from the shared bit line BLC to the bit line BLA is supplied to the MTJ element 8A, and the write current IwB running from the shared bit line BLC to the bit line BLB is supplied to the MTJ element 8B.

In the first half of the activation period of the selected word line, the two MTJ elements 8A and 8B are set to the same resistance state by the write currents IwA and IwB from the shared bit line BLC. For example, when the reference layers of the MTJ elements 8A and 8B are connected to the connection node nd, the resistance states of the two MTJ elements 8A and 8B in the selected cell MC become the “H” state.

In the second half of the activation period of the selected word line, the potential of the shared bit line BLC is set to the “L” level from the “H” level. The potential of the selected bit line BLA is set to the “H” level from the “L” level, and the potential of the selected bit line BLB is kept at the “L” level.

As a result of such control of the potentials of the bit lines BLA, BLB, and BLC, the write current IwA running from the bit line BLA to the shared bit line BLC is supplied to the MTJ element 8A. As the bit line BLB and the bit line BLC are at the same potential level, almost no write current runs through the MTJ element 8B. The write current IwA from the bit line BLA tends to run toward the shared bit line BLC having a low resistance value rather than the bit line BLB to which the MTJ element (resistive element) is connected. Therefore, even if the potential of the bit line BLB is lower than the potential of the bit line BLA, most of the write current IwA runs through the shared bit line BLC, so that a diverted current of the write current IwA does not change the resistance state of the MTJ element 8B.

For example, in the selected memory cell MC, the resistance state of the MTJ element 8A changes from the “H” state to the “L” state. On the other hand, the resistance state of the MTJ element 8B is kept at the “H” state.

After the two MTJ elements 8A and 8B in the selected cell MC are thus changed from the same resistance state to different resistance states, the selected word line is inactivated, and the selected bit lines BLA, BLB, and BLC are inactivated.

The write operation for the selected cell shown in FIG. 8 is completed as described above.

In the write operation shown in FIG. 8, the resistance state of the MTJ element 8A on the side of the bit line BLA of the two MTJ elements 8A and 8B in the memory cell MC is the “L” state, and the resistance state of the MTJ element 8B on the side of the bit line BLB is the “H” state. Thus, as a result of the write operation shown in FIG. 8, the resistance states of the two MTJ elements 8A and 8B in the memory cell MC are opposite to the resistance states of the two MTJ elements 8A and 8B in the write operation shown in FIG. 7. That is, the write operation shown in FIG. 8 makes it possible to write, into the memory cell MC, data (e.g., “0”) reverse to data (e.g., “1”) in the write operation shown in FIG. 7.

The read operation for the MRAM shown in FIG. 8 is the same as that in the example shown in FIG. 7, and the read operation shown in FIG. 8 is therefore not described. However, in FIG. 8, the data reverse to the data written in the write operation shown in FIG. 7 is written into the memory cell, so that the difference value produced by the sense amplifier 55 is, for example, a reverse value (reverse polarity) of the difference value obtained by the read operation shown in FIG. 7.

The write operation and read operation in the MRAM according to the present embodiment are performed as shown in FIG. 7 and FIG. 8.

As described above, in the MRAM according to the present embodiment, the memory cell MC is formed of the two MTJ elements 8A and 8B and the two select transistors TrA and TrB.

In the MRAM according to the present embodiment, the MTJ elements 8A and 8B and the select transistors TrA and TrB are located in the vicinity of each other in the same memory cell array. Therefore, in the operation of the MRAM according to the present embodiment, the deterioration of the write operation and read operation in the memory caused by the characteristic variations of the components in the memory cell is inhibited. As a result, operation reliability is improved and memory cell operation can be stabilized in the write operation and read operation in the MRAM according to the present embodiment.

In the MRAM according to the present embodiment, the operation of the memory cell MC is controlled by the control of the potential of the bit line (shared bit line) BLC shared by the two MTJ elements 8A and 8B. Thus, in the write operation and read operation in the MRAM according to the present embodiment, the variations in the application potentials and supply currents for the two MTJ elements 8A and 8B can be reduced. Consequently, the writing margin and the reading margin can be improved in the operation of the MRAM according to the present embodiment.

The read operation of the MRAM according to the present embodiment is performed by the differential reading that uses the two MTJ elements 8A and 88 included in one memory cell MC. Thus, one memory cell can be differentially read such that the reading margin can be larger in the read operation of the MRAM according to the present embodiment than when data is read from one memory cell by single-end reading.

Depending on the characteristics of the MTJ element, the intensity and application period of the current pulse (voltage pulse) for changing the resistance state of the MTJ element from the “L” state to the “H” state may be different from the intensity and application period of the current pulse for changing the resistance state of the MTJ element from the “H” state to the “L” state. In this case, to stabilize the operation, the operation periods of the memory are homogenized by circuit-based control so that the operation for changing the resistance state to the high-resistance state and the operation for changing the resistance state to the low-resistance state are equal in period. For example, the circuits and operation of the memory are designed so that the operation period in which a short period is required for a resistance change is set to same length to the operation period in which a long period is required for a resistance change.

In the write operation in the MRAM according to the present embodiment, both the operation for changing the resistance states of the MTJ elements 8A and 8B to the “L” state and the operation for changing the resistance states of the MTJ elements 8A and 8B to the “H” state are performed in one write cycle. Thus, the circuit control for the homogenized operation can be reduced, and the load on the circuits can be reduced.

As described above, according to the resistance change type memory in the present embodiment, memory operation characteristics can be improved.

(2) Modifications

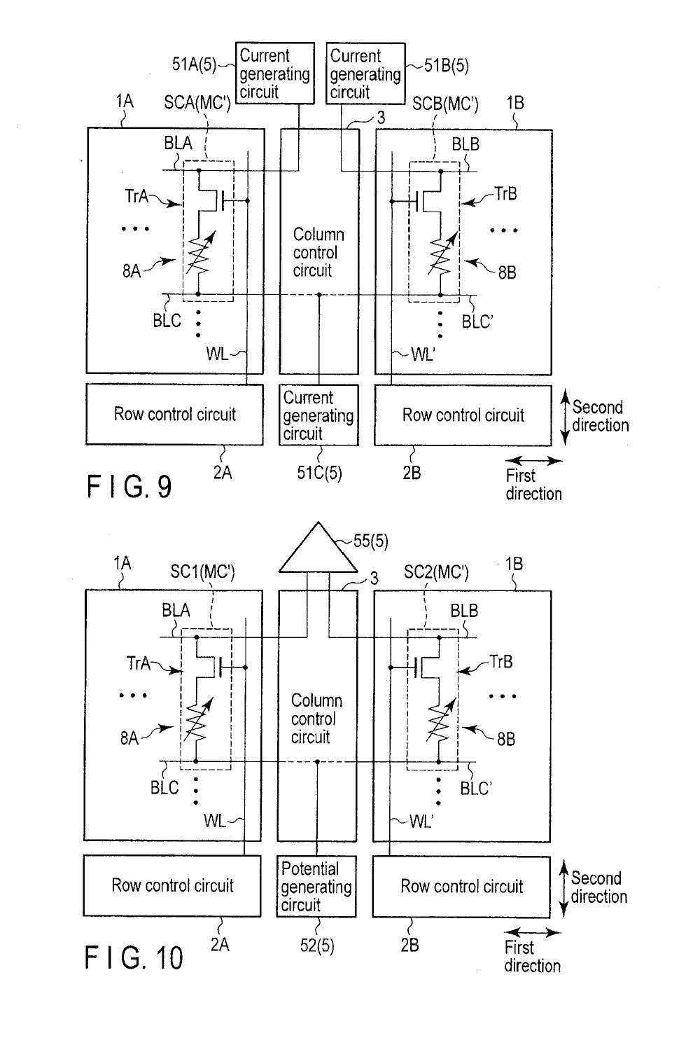

Modifications of the resistance change type memory according to the present embodiment are described with reference to FIG. 9 to FIG. 13. Components in the following modifications substantially equivalent to those in the above embodiment are given the same reference signs and are repeatedly described when necessary.

(a) Modification 1

Modification 1 of the resistance change type memory according to the present embodiment is described with reference to FIG. 9 and FIG. 10.

In the example shown in FIG. 3, the two MTJ elements 8A and 8B and the select transistors TrA and TrB forming one memory cell MC are provided in one memory cell array 1A.

However, as in the modification shown in FIG. 9 and FIG. 10, two cells SCA and SCB that form one memory cell MC′ may be provided in different memory cell arrays 1A and 1B.

As shown in FIG. 9 and FIG. 10, the memory cell array 1A and the memory cell array 1B are adjacent to each other in the column direction (first direction) across the column control circuit 3. The cell SCA is provided in the memory cell array 1A, and the cell SCB is provided in the memory cell array 1B.

The cell SCA includes the select transistor TrA and the MTJ element 8A. One end of the current path of the select transistor TrA is connected to the bit line BLA in the memory cell array 1A, and the other end of the current path of the select transistor TrA is connected to one end of the MTJ element 8A. The other end of the MTJ element 8A is connected to the bit line BLC in the memory cell array 1A. The gate of the select transistor TrA is connected to the word line WL.

The cell SCB includes the select transistor TrB and the MTJ element 8B. One end of the current path of the select transistor TrB is connected to the bit line BLB, and the other end of the current path of the select transistor TrB is connected to one end of the MTJ element 8B. The other end of the MTJ element 8B is connected to a bit line BLC′.

The bit lines BLB and BLC′ connected to the cell SCB is provided in the memory cell array 1B. For example, the bit line BLC′ in the memory cell array 1B may be connected to the bit line BLC in the memory cell array 1A via the column control circuit 3. The bit lines BLC and BLC′ may be separated from each other as long as the bit lines BLC and BLC′ are controlled at the common potential by the control circuit 7 or the column control circuit 3 shown in FIG. 1.

The gate of the select transistor TrB is connected to a word line WL′ provided in the memory cell array 1B. The word line WL′ is driven by the row control circuit 2B. The word lines WL and WL′ of the cells SCA and SCB may be electrically connected to each other, or may be driven by the common row control circuit.

The two cells SCA and SCB provided in the different memory cell arrays 1A and 1B form one memory cell MC′.

FIG. 9 shows the connection between the memory cell MC′ and the write/read circuit in the write operation in the MRAM according to the present modification. FIG. 10 shows the connection between the memory cell MC′ and the write/read circuit in the read operation in the MRAM according to the present modification.

In the write operation and read operation in the MRAM, the control circuit 7 shown in FIG. 1 recognizes, for example, by the addresses of the bit lines BLA, BLB, BLC, and BLC′ and the word lines WL and WL′ to which the two cells SCA and SCB are connected, that the two cells SCA and SCB in the different memory cell arrays 1A and 1B form one memory cell MC′.

The control circuit 7 then controls the connection between the bit lines BLA, BLB, BLC, and BLC′ and the write/read circuit 5 for the cells SCA and SCB respectively provided in the different memory cell arrays 1A and 1B and also controls the activation of the word lines WL and WL′, thereby performing the write operation and read operation for the memory cell that includes the two cells SCA and SCB shown in FIG. 7 and FIG. 8.

As shown in FIG. 9, during the write operation, the bit line BLA and the bit line BLC are respectively connected to the current generating circuits 51A and 51C via the column control circuit 3 in the cell SCA in the memory cell array 1A. In the cell SCB in the memory cell array 1B, the bit line BLB is connected to the current generating circuit 51B via the column control circuit 3, and the bit line BLC′ is connected to, for example, the current generating circuit 51C shared with the bit line BLC. The bit lines BLC and BLC′ connected to the cells SCA and SCB may be connected to different current generating circuits. As a result of the connection shown in FIG. 9, the MTJ elements 8A and 8B forming the memory cell MC′ are supplied with write currents, and the write operation shown in FIG. 7 and FIG. 8 is performed.

As shown in FIG. 10, during the read operation, the bit line BLA is connected to one input terminal of the sense amplifier 55 via the column control circuit 3 in the cell SCA in the memory cell array 1A. In the cell SCB in the memory cell array 1B, the bit line BLB is connected to the other input terminal of the sense amplifier 55 via the column control circuit 3. The bit line BLC and the bit line BLC′ are connected to a fixed potential (e.g., ground or power supply).

As a result of the connection shown in FIG. 10, the MTJ elements 8A and 8B forming the memory cell MC′ are supplied with read currents, and the differential reading is performed.

As shown in FIG. 9 and FIG. 10, even when the two cells SCA and SCB that form one memory cell MC′ as a control unit are provided in the different memory cell arrays 1A and 1B, the operation shown in FIG. 7 and FIG. 8 can be performed under the control of the control circuit.

In the present modification, during the write operation, the MTJ elements 8A and 8B in the cells SCA and SCB are set in the same state, and then the cells SCA and SCB that do not change the resistance states of the MTJ elements may be electrically separated from the current generating circuits 51A, 51B, and 51C. This allows the potential control of the bit lines during the write operation to be easier.

In the MRAM according to the embodiment shown in FIG. 3, the two cells SCA and SCB that form the memory cell MC are provided in the same memory cell array. Thus, the characteristic variations of the memory elements 8A and 8B and the select transistors TrA and TrB forming the memory cell MC can be reduced in the MRAM shown in FIG. 3 as compared with the case where the cells SCA and SCB are provided in different cell arrays 1A and 1B as in the present modification.

Furthermore, in the MRAM according to the embodiment, the select transistors TrA and TrB can be turned on/off under the control of one word line. Therefore, in the MRAM according to the embodiment, the word line can be more easily controlled than when different word lines WL and WL′ are connected to the two cells SCA and SCB. Moreover, the MRAM according to the embodiment enables the power consumption to be reduced by the sharing of the word line WL and the bit line.

Still further, in the MRAM according to the embodiment, the two cells SCA and SCB share one bit line BLC, so that the variations of the write current and the read current supplied to one memory cell can be inhibited.

(b) Modification 2

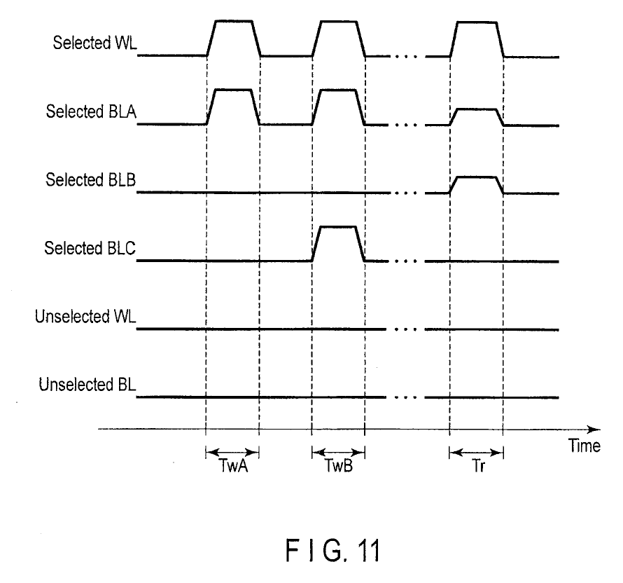

Modification 2 of the MRAM according to the embodiment is described with reference to FIG. 11.

In the operation of the MRAM shown in the embodiment, the resistance states (resistance values) of two MTJ elements are changed in one write cycle.

However, the resistance states of the two MTJ elements 8A and 8B in the memory cell MC can be changed in different operation cycles.

As shown in FIG. 11, a selected word line is activated. The selected bit lines BLA, BLB, and BLC are then activated.

In the present modification, for example, the potential of the selected bit line BLA is set to the “H” level, and the potential of the shared bit line BLC is set to the “L” level, in a first write cycle TwA for one memory cell. The potential of the bit line BLB is set to the same potential as the shared bit line BLC.

In this case, the write current IwA running from the bit line BLA to the shared bit line BLC is supplied to the MTJ element 8A. On the other hand, as the bit line BLB and the shared bit line BLC are equipotential, almost no current runs through the MTJ element 8B as described above.

As a result, the resistance state of the MTJ element 8A connected to the bit line BLA is changed, and the resistance state of the MTJ element 8B connected to the bit line BLB is not changed.

After the resistance state of the MTJ element 8A on the side of the bit line BLA is changed, the selected word line and the selected bit lines are inactivated. The selected word line is then again activated to change the resistance state of the MTJ element 8B on the side of the bit line BLB.

The resistance state of the MTJ element 8B on the side of the bit line BLB is opposite to the resistance state of the MTJ element 8A on the side of the bit line BLA. That is, the write current IwB running in a direction opposite to the write current passed through the MTJ element 8A is supplied to the MTJ element 8B.

Here, as shown in FIG. 11, in a second write cycle TwB for one memory cell, the potential of the shared bit line BLC is set to the “H” level, and the bit line BLB is set to the “L” level. The bit line BLA is set to the same potential as the shared bit line BLC.

The write current IwB running from the shared bit line BLC to the bit line BLB is supplied to the MTJ element 8B on the side of the bit line BLB. As the bit line BLA and the shared bit line BLC are equipotential, almost no current runs through the MTJ element 8A on the side of the bit line BLA.

As a result, the resistance state of the MTJ element 8B connected to the bit line BLB is changed to a state opposite to the resistance state of the MTJ element 8A connected to the bit line BLA. At the same time, the resistance state of the MTJ element 8A is not changed.

Thus, in the write operation in the MRAM according to the present modification, the resistance states of the two MTJ elements 8A and 8B in one memory cell MC are changed to different states in the two write cycles TwA and TwB.

In other words, the resistance state of one MTJ element in the memory cell MC alone can be changed. Thus, in the event of a failure in which the two MTJ elements 8A and 8B in the memory cell MC are in the same resistance state after a write operation, the resistance state of one MTJ element can be selectively changed. Consequently, according to the present modification, the reliability of the MRAM can be improved.

When the word line WL is activated twice in the write operation for one memory cell, a word line inactivating period is secured between the first word line activating period and the second word line activating period. In contrast, in the MRAM according to the embodiment, the word line is kept active so that the two MTJ elements are changed to different resistance states. Thus, the word line inactivating period can be reduced as compared with the case where the word line is activated twice.

As described above, in the MTJ element, the period for changing from the high-resistance state to the low-resistance state may be different from the period for changing from the low-resistance state to the high-resistance state. In this case, the current/voltage supplied to the memory element is adjusted or the operation cycle in which the period for changing the resistance state is short is prolonged to homogenize the operation cycles (average the periods).

In the operation of the MRAM according to the embodiment, one operation cycle for the memory cell includes both the operation for changing the memory element to the high-resistance state and the operation for changing the memory element to the low-resistance state. Therefore, in the MRAM according to the embodiment, the operations for changing the resistance states of the two MTJ elements 8A and 8B are successively performed, so that the period in which the word line is activated can be reduced, and no complex control for homogenizing the operation is needed.

(c) Modification 3

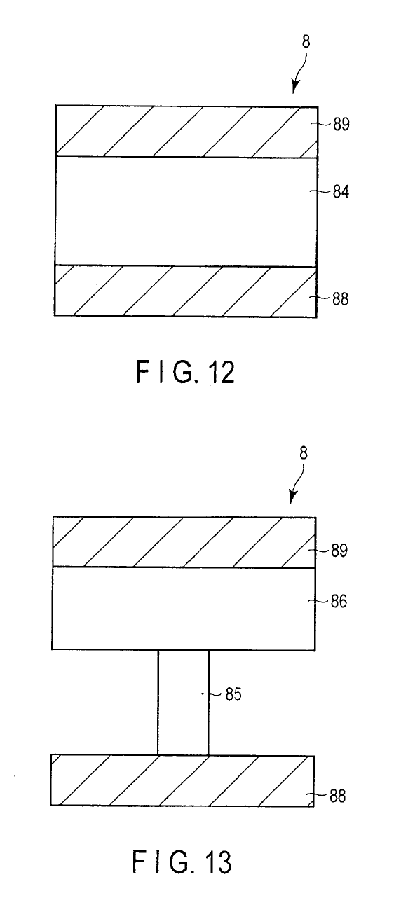

Modification 3 of the resistance change type memory is described with reference to FIG. 12 and FIG. 13.

In the embodiment described above, the MRAM is shown as an example of the resistance change type memory. However, the resistance change type memory may be a resistance change type memory other than the MRAM, such as a resistive RAM (ReRAM) and a phase change RAM (PCRAM).

For example, in the ReRAM, a variable resistive element is used as a memory element. The memory element used in the ReRAM is reversibly changed in resistance value by energy such as a voltage, a current, or heat, and maintains the changed resistance value in a nonvolatile manner.

FIG. 12 shows a structure example of the memory element (variable resistive element) 8 used in the ReRAM.

The variable resistive element 8 as the memory element 8 includes a lower electrode 88, an upper electrode 89, and a resistance change film (recording layer) 84 intervening between these electrodes. The resistance change film 84 is made of a metal oxide such as a perovskite-like metal oxide or a binary metal oxide. The perovskite-like metal oxide includes, for example, PCMO (Pr_{0.7}Ca_{0.3}MnO₃), Nb-added SrTi(Zr)O₃, and Cr-added SrTi(Zr)O₃. The binary metal oxide includes, for example, NiO, TiO₂, and Cu₂O.

For example, the resistance state of the resistance change film 84 changes with the production or disappearance of a micro current path (filament) in the resistance change film 84, or the movement (concentration profile change) of elements (ions) that form the resistance change film 84.

The variable resistive element 8 includes an element of an operation mode called a bipolar type and an element of an operation mode called a unipolar type.

The resistance value of the bipolar type element 8 changes in accordance with the change of the polarity of a voltage applied thereto. The resistance value of the unipolar type element 8 changes in accordance with the change of one or both of the absolute value and pulse width of a voltage applied thereto. Thus, the variable resistive element 8 as the memory element changes to the low-resistance state or the high-resistance state by the control of the applied voltage. Whether the variable resistive element 8 is the bipolar type or the unipolar type may be determined by the material of the resistance change film 84 and by the combination of the materials of the resistance change film 84 and the electrodes 88 and 89.

The operation of writing into the variable resistive element 8 as the memory element 8, that is, the operation of changing the resistance state of the variable resistive element 8 is called a reset operation/set operation.

When the variable resistive element 8 is brought into the high-resistance state, a reset voltage is applied to the element 8. When the variable resistive element 8 is brought into the low-resistance state, a set voltage is applied to the element 8.

In order to read data, a read voltage sufficiently lower than the set voltage and the reset voltage is applied to the variable resistive element 8, and a current running through the variable resistive element 8 at the same time is detected to determine the resistance state of the variable resistive element 8.

In the PCRAM, a phase change element is used as the memory element 8. The crystalline phase of the phase change element 8 reversibly changes from a crystalline state to a noncrystalline state or from a noncrystalline state to a crystalline state due to externally applied energy. As a result of the change of state in crystalline phase, the resistance value (impedance) of the phase change element changes. The condition in which the crystalline phase of the phase change element has changed is retained in a nonvolatile manner until energy necessary to change the crystalline phase is provided.

FIG. 13 shows a structure example of the memory element (phase change element) used in the PCRAM. The phase change element 8 as the memory element includes a lower electrode 88, a heater layer 85, a phase change film (recording layer) 86, and an upper electrode 89 that are stacked.

The phase change film 86 is made of a phase change material, and is changed into a crystalline state or a noncrystalline (amorphous) state by heat generated during writing. The material of the phase change film 86 includes chalcogenide such as Ge—Sb—Te, In—Sb—Te, Ag—In—Sb—Te, and Ge—Sn—Te. These materials are preferable in ensuring high-speed switching performance, repeated recording stability, and high reliability.

The heater layer 85 is in contact with the bottom surface of the phase change film 86. The area of contact of the heater layer 85 with the phase change film 86 is preferably smaller than the area of the bottom surface of the phase change film 86. The purpose of this is to decrease a write current or voltage by reducing the contact part between the heater layer 85 and the phase change film 86 to reduce a heated part. The heater layer 85 is made of a conducting material, and is preferably made of, for example, a material selected from the group consisting of a high melting point metal, TiN, WN, MoN, an aluminum alloy, and a copper alloy. Moreover, the heater layer 85 may be made of the same material as the lower electrode 88.

The area of the lower electrode 88 is larger than the area of the heater layer 85. The upper electrode 89 has, for example, the same planar shape as the phase change film 86. The material of the lower electrode 88 and the upper electrode 89 includes a high melting point metal such as Ta, Mo, or W.

The heating temperature of the phase change film 86 is changed by controlling the intensity and width of a current pulse applied to this phase change film 86, and the phase change film 86 changes into the crystalline state or noncrystalline state.

The crystalline state of the phase change film 86 is changed to write into the phase change element 8 as the memory element.

In a write operation, a voltage or a current is applied across the lower electrode 88 and the upper electrode 89, and a current is passed to the lower electrode 88 from the upper electrode 89 via the phase change film 86 and the heater layer 85. Heat is generated in the phase change element by this current. If the phase change film 86 is heated to near the melting point, the phase change film 86 changes into a noncrystalline phase (high-resistance state). The phase change film 86 maintains the noncrystalline state even when the application of the voltage or current is stopped. On the other hand, a voltage or a current is applied across the lower electrode 88 and the upper electrode 89. If the phase change film 86 is heated to near a temperature suitable for crystallization, the phase change film 86 changes into a crystalline phase (low-resistance state). The phase change film 86 maintains the changed crystalline state even when the application of the voltage or current is stopped. When the phase change film 86 is changed into the crystalline state, the set intensity of the current pulse applied to the phase change film 86 is lower and the set width of the current pulse is greater than, for example, when the phase change film 86 is changed into the noncrystalline state.

The resistance state of the phase change film 86, that is, whether the phase change film 86 is in the crystalline phase or the noncrystalline phase can be known by applying, across the lower electrode 88 and the upper electrode 89, such a low voltage or low current that does not cause the phase change film 86 to be crystalline or noncrystalline and reading the current running through the element 8.

As described above, in the resistance change memory according to the present embodiment, the variable resistive element or the phase change element may be used as the memory element 8 instead of the magnetoresistive effect element (MTJ element) 8. The resistance state of such a memory element 8 is changed by the shape of a write pulse supplied to the element 8, for example, by at least one of the polarity (a current flowing direction, or the positive and negative of a voltage) of the pulse, the intensity (a current value or voltage value) of the pulse, and the application time (pulse width) of the pulse.

The memory cell of the resistance change type memory according to the present embodiment is formed by a memory element other than the magnetoresistive effect element (MTJ element). Even in this case, the operation characteristics of the resistance change type memory can be improved as has been described in the embodiment.

[Others]

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resistance change type memory comprising:
first to third bit lines extending in a first direction;
a word line extending in a second direction, the second direction intersecting with the first direction; and
a memory cell including a first cell connected between the first and third bit lines and a second cell connected between the second and third bit lines,
the first cell including a first transistor and a first memory element,
the first transistor including a first control terminal connected to the word line and a first current path,
the first memory element including a first terminal connected to one end of the first current path and a second terminal, the resistance state of the first memory element changing to a first resistance state or a second resistance state different from the first resistance state in accordance with a write pulse to be supplied,
the second cell including a second transistor and a second memory element,
the second transistor including a second control terminal connected to the word line and a second current path,
the second memory element including a third terminal connected to one end of the second current path and a fourth terminal, the resistance state of the second memory element changing to the first or second resistance state in accordance with a write pulse to be supplied.

2. The resistance change type memory according to claim 1, wherein
during a write operation for the memory cell, one of the first and second memory elements is changed to the first resistance state, and then the other of the first and second memory elements is changed to the second resistance state, in a period in which the word line is activated.

3. The resistance change type memory according to claim 2, wherein
during the write operation for the memory cell, a first potential level is applied to the first and second bit lines, and a second potential level different from the first potential level is applied to the third bit line, in the first half of the period in which the word line is activated, and
the second potential level is applied to one of the first and second bit lines, the first potential level is applied to the other of the first and second bit lines, and the first potential level is applied to the third bit line, in the second half of the period in which the word line is activated.

4. The resistance change type memory according to claim 1, wherein
in a data retention state of the memory cell,
the first and second memory elements have different resistance states, and
the different resistance states of the first and second memory elements are associated with data stored in the memory cell.

5. The resistance change type memory according to claim 1, further comprising:
a sense amplifier which includes a first input terminal connected to the first bit line and a second input terminal connected to the second bit line during a read operation for the memory cell; and
a potential generating circuit which applies a potential to the third bit line during the read operation for the memory cell.

6. The resistance change type memory according to claim 5, wherein
the sense amplifier and the potential generating circuit respectively supply, to the first and second memory elements via the first to third bit lines, a read pulse that does not change the resistance states of the first and second memory elements, and
the sense amplifier determines, as data in the memory cell, a difference value based on the resistance states of the first and second memory elements.

7. The resistance change type memory according to claim 1, wherein
the third bit line is provided between the first and second bit lines, and
the first cell and the second cell are adjacent to each other in the second direction to share the third bit line.

8. The resistance change type memory according to claim 1, wherein
the first terminal of the first memory element and the third terminal of the second memory element are first-polarity terminals, and the second terminal of the first memory element and the fourth terminal of the second memory element are second-polarity terminals different from the first polarity, and
the second and fourth terminals are located on the side of the third bit line.

9. The resistance change type memory according to claim 1, wherein
during the write operation for the memory cell,
the word line is activated, the first bit line is set to a first potential level, and the second and third bit lines are set to a second potential level different from the first potential level,
the word line is inactivated, and the first to third bit lines are set to the second potential level, and
the word line is activated, the first and third bit lines are set to the first potential level, and the second bit line is set to the second potential level.

10. The resistance change type memory according to claim 1, wherein
the first cell and the second cell are provided in the same cell array.

11. The resistance change type memory according to claim 1, wherein
the first cell is provided in a first cell array, and the second cell is provided in a second cell array different from the first cell array.

12. The resistance change type memory according to claim 11, further comprising:
a column control circuit which controls columns of the first and second cell arrays;
a first row control circuit which controls a row of the first cell array; and
a second row control circuit which controls a row of the second cell array,
wherein the first cell array and the second cell array are adjacent in the first direction across the column control circuit.

13. A resistance change type memory comprising:
first to third bit lines which extend in a first direction;
word lines extending in a second direction, the second direction intersecting with the first direction; and
memory cells in a memory cell array, each of the memory cells including a first memory element and a first transistor connected between the first and third bit lines, and a second memory element and a second transistor connected between the second and third bit lines,
the first transistor including a first control terminal connecting the word lines and a first current path, the first memory element including a first terminal connected to one end of the first current path and a second terminal, the second transistor including a second control terminal connected to the word lines and a second current path, the second memory element including a third terminal connected to one end of the second current path and a fourth terminal,
wherein the resistance states of the first and second memory elements change to a first resistance state or a second resistance state different from the first resistance state in accordance with a write pulse to be supplied.

14. The resistance change type memory according to claim 13, wherein
during a write operation for the memory cell, one of the first and second memory elements are changed to the first resistance state, and then one of the first and second memory elements is changed to the second resistance state, in a period in which the selected word line is activated.

15. The resistance change type memory according to claim 13, wherein
in a data retention state of the memory cell,
the first and second memory elements have different resistance states, and
the different resistance states of the first and second memory elements are associated with data stored in the memory cell.

16. The resistance change type memory according to claim 13, further comprising:
a sense amplifier which includes a first input terminal connected to the first bit line and a second input terminal connected to the second bit line during a read operation for the memory cell; and
a potential generating circuit which applies a potential to the third bit line during the read operation for the memory cell,
wherein the sense amplifier and the potential generating circuit respectively supply, to the first and second memory elements via the first to third bit lines, a read pulse that does not change the resistance states of the first and second memory elements, and
the sense amplifier determines, as data in the memory cell, a difference value based on the resistance states of the first and second memory elements.

17. The resistance change type memory according to claim 13, wherein
the first terminal of the first memory element and the third terminal of the second memory element are first-polarity terminals, and the second terminal of the first memory element and the fourth terminal of the second memory element are second-polarity terminals different from the first polarity, and
the second and fourth terminals are located on the side of the third bit line.
